(19) United States
(12) Patent Application Publication
(10) Pub. No.: US 2015/0310971 A1
(43) Pub. Date: Oct. 29, 2015

(54) MAGNETIC MATERIAL AND METHOD THEREFOR

(71) Applicant: United Technologies Corporation, Hartford, CT (US)

(72) Inventors: Michael A. Kmetz, Colchester, CT (US); Gavin Charles Richards, Poughkeepsie, NY (US); Steven Lawrence Suib, Storrs, CT (US); Rebecca Eve Gottlieb, Windham, CT (US)

(21) Appl. No.: 14/696,729

(22) Filed: Apr. 27, 2015

Related U.S. Application Data
(60) Provisional application No. 61/984,106, filed on Apr. 25, 2014.
(60) Provisional application No. 61/984,133, filed on Apr. 25, 2014.

(51) Int. Cl. H01F 1/04; B05D 1/18; C23C 16/04; C23C 16/32; C23C 18/32; H01F 41/02; C23C 16/16

(52) U.S. Cl. CPC H01F 1/04; H01F 41/02; B05D 1/18; C23C 16/16; C23C 16/325; C23C 18/32; C23C 16/045

(57) ABSTRACT

An article includes at least one fiber that has a fiber core. An interface layer extends around the fiber core. The interface layer includes a ceramic matrix and ferromagnetic regions dispersed through the ceramic matrix.

### CROSS REFERENCE TO RELATED APPLICATIONS

The present disclosure claims priority to U.S. Provisional Patent Application No. 61/984,106 filed on 25 Apr. 2014 and U.S. Provisional Patent Application No. 61/984,133 filed on 25 Apr. 2014.

### BACKGROUND

Magnetic materials are known and used in a wide variety of end applications. Example magnetic materials can include a monolithic structure formed of a magnetic material or a composite of magnetic material particles mixed with an organic binder. However, such magnetic materials are environmentally limited to relatively low-temperature uses because of thermal degradation of the organic binder and/or thermally-induced oxidation that causes loss of magnetic properties.

### SUMMARY

An article according to an example of present disclosure includes at least one fiber that includes a fiber core, and an interface layer that extends around the fiber core. The interface layer includes a first ceramic matrix and ferromagnetic regions dispersed through the first ceramic matrix.

In a further embodiment of any of the foregoing embodiments, the first ceramic matrix is an oxide.

In a further embodiment of any of the foregoing embodiments, the first ceramic matrix is an oxide of at least one of silicon, aluminum, chromium, yttrium, zirconium, hafnium, and titanium.

In a further embodiment of any of the foregoing embodiments, the ferromagnetic regions include cobalt.

In a further embodiment of any of the foregoing embodiments, the ferromagnetic regions include at least one of cobalt, iron, nickel, samarium, oxide, and ferromagnetic intermetallic.

In a further embodiment of any of the foregoing embodiments, the ferromagnetic regions are nanosized.

In a further embodiment of any of the foregoing embodiments, the fiber core is formed of at least one of an oxide, carbide, and silicon-based material.

A further embodiment of any of the foregoing embodiments includes a non-magnetic interface layer that is located radially between the fiber core and the interface layer.

In a further embodiment of any of the foregoing embodiments, the non-magnetic interface layer includes at least one of carbon, boron nitride, silicon nitride, and silicon carbide.

A further embodiment of any of the foregoing embodiments includes a second ceramic matrix differing in composition from the first ceramic matrix. The second ceramic matrix embeds at least one fiber and the interface layer.

A further embodiment of any of the foregoing embodiments includes a protective layer that is located on the interface layer such that the interface layer is located radially between the protective layer and the fiber core.

In a further embodiment of any of the foregoing embodiments, the protective layer includes at least one of silicon carbide, silicon nitride, silicon dioxide, alumina, and chromia.

A method of fabricating an article according to an example of the present disclosure includes forming an interface layer around a fiber core of at least one fiber. The interface layer includes a first ceramic matrix and ferromagnetic regions dispersed through the ceramic matrix.

In a further embodiment of any of the foregoing embodiments, the forming includes forming the first ceramic matrix and the ferromagnetic regions from a sol-gel process.

A further embodiment of any of the foregoing embodiments includes applying to the fiber core a sol that has a ferromagnetic metal and at least one of aluminum, silicon, chromium, yttrium, zirconium, hafnium, and titanium.

A further embodiment of any of the foregoing embodiments includes removing solvent from the sol to form a gel, and thermally treating the gel to form the first ceramic matrix and the ferromagnetic regions.

A further embodiment of any of the foregoing embodiments includes embedding at least one fiber in a second ceramic matrix that differs in composition from the first ceramic matrix.

A further embodiment of any of the foregoing embodiments includes applying a protective layer on the first ceramic matrix such that the first ceramic matrix is located radially between the protective layer and the fiber core.

A magnetic article according to an example of the present disclosure includes a porous structure that includes internal pores, and an interface layer that lines at least the internal pores. The interface layer includes a first non-magnetic ceramic matrix and ferromagnetic regions dispersed through the first non-magnetic ceramic matrix and a second non-magnetic ceramic matrix that lines the interface layer. The second non-magnetic ceramic matrix is different in composition from the first non-magnetic ceramic matrix.

A magnetic article according to an example of the present disclosure includes a ceramic matrix, and a plurality of filler structures dispersed through the ceramic matrix. At least one of the filler structures includes a substrate, a ferromagnetic layer around the substrate, and a ceramic barrier layer that encloses the ferromagnetic layer.

In a further embodiment of any of the foregoing embodiments, the ferromagnetic layer includes a metal selected from the group consisting of cobalt, iron, nickel, gadolinium, and combinations thereof.

In a further embodiment of any of the foregoing embodiments, the ferromagnetic layer includes a magnetic oxide.

In a further embodiment of any of the foregoing embodiments, the substrate is selected from the group consisting of a fiber, a hollow particle, and a solid particle.

In a further embodiment of any of the foregoing embodiments, the substrate is hollow.

In a further embodiment of any of the foregoing embodiments, the substrate is solid.

In a further embodiment of any of the foregoing embodiments, the ceramic barrier layer includes an oxide.

In a further embodiment of any of the foregoing embodiments, the ceramic barrier layer is selected from the group consisting of silicon oxides, aluminum oxides, chromium oxides, and combinations thereof.

In a further embodiment of any of the foregoing embodiments, the ceramic matrix is selected from the group consisting of carbides, nitrides, oxides, silicides, aluminides, and combinations thereof.

A filler for a magnetic composite material according to an example of the present disclosure includes a filler structure that includes a substrate, a ferromagnetic layer around the substrate, and a ceramic barrier layer that encloses the ferromagnetic layer.

In a further embodiment of any of the foregoing embodiments, the ferromagnetic layer includes a metal selected from the group consisting of cobalt, iron, nickel, gadolinium, and combinations thereof.

In a further embodiment of any of the foregoing embodiments, the ferromagnetic layer includes a magnetic oxide.

In a further embodiment of any of the foregoing embodiments, the substrate is selected from the group consisting of a fiber, a hollow particle, and a solid particle.

In a further embodiment of any of the foregoing embodiments, the substrate is hollow.

In a further embodiment of any of the foregoing embodiments, the substrate is solid.

In a further embodiment of any of the foregoing embodiments, the ceramic barrier layer includes an oxide.

In a further embodiment of any of the foregoing embodiments, the ceramic barrier layer is selected from the group consisting of silicon oxides, aluminum oxides, chromium oxides, and combinations thereof.

A method of fabricating a magnetic article according to an example of the present disclosure includes depositing a ferromagnetic layer around a substrate of a filler structure, and depositing a ceramic barrier layer that encloses the ferromagnetic layer.

A further embodiment of any of the foregoing embodiments includes embedding the filler structure in a ceramic matrix.

In a further embodiment of any of the foregoing embodiments, the ferromagnetic layer includes at least one of cobalt, iron, nickel, gadolinium, a magnetic oxide, and combinations thereof. The substrate is selected from the group consisting of a fiber, a hollow particle, and a solid particle, and the ceramic barrier layer includes an oxide.

### BRIEF DESCRIPTION OF THE DRAWINGS

The various features and advantages of the present disclosure will become apparent to those skilled in the art from the following detailed description. The drawings that accompany the detailed description can be briefly described as follows.

FIG. 1 illustrates an example article that has a fiber core and a magnetic interface layer.

FIG. 2 illustrates another example article that has a fiber core, a magnetic interface layer, and a non-magnetic interface layer.

FIG. 3 illustrates another example article that has a fiber core, a magnetic interface layer, a non-magnetic interface layer, and a protective layer.

FIG. 4 illustrates another example article in which a fiber core with a magnetic interface layer are embedded in a matrix.

FIG. 5 illustrates an example magnetic article.

FIG. 6 illustrates a representative example of a filler structure that includes a fiber.

FIG. 7 illustrates a representative example of a filler structure that includes a hollow substrate.

FIG. 8 illustrates a representative example of a filler structure that includes a solid particle.

FIG. 9 illustrates a representative example of a filler structure having multiple ferromagnetic layers and multiple ceramic barrier layers.

### DETAILED DESCRIPTION

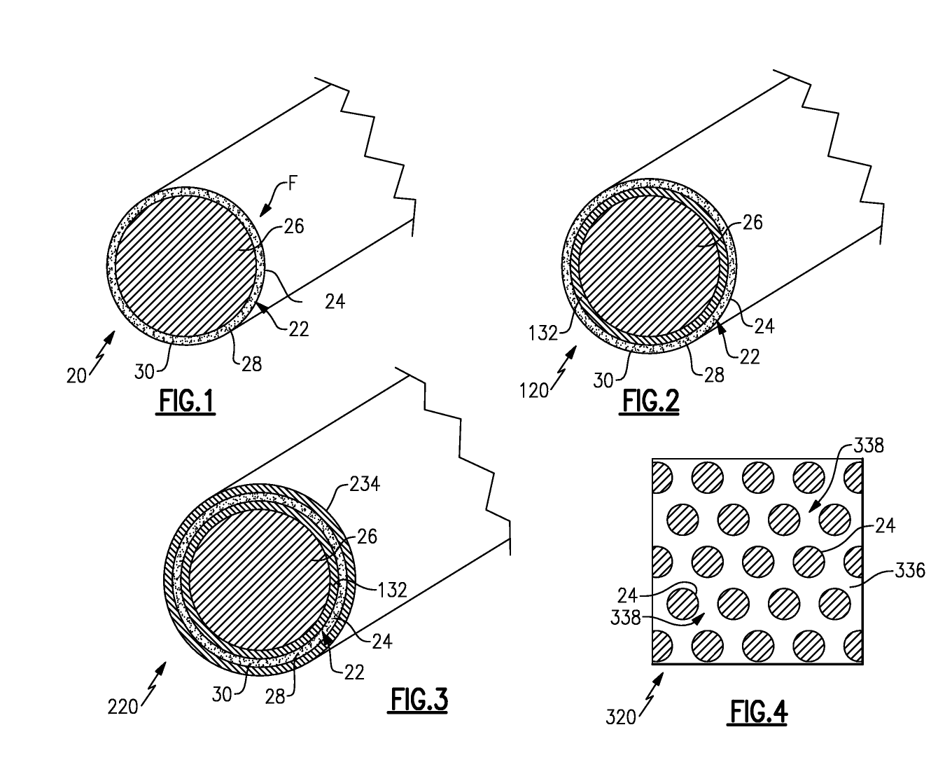

FIG. 1 illustrates an example article 20 that includes a magnetic material 22. In this example, the magnetic material 22 is formed and utilized as a magnetic interface layer 24 that extends around a fiber core 26 of at least one fiber (represented at “F”). Although the examples herein may be described with reference to layers, fibers, fiber cores, fiber-reinforced materials, or the like, this disclosure also extends to other forms and uses of the magnetic material 22.

Magnetic materials that have a monolithic structure or that are mixed with organic binders have limited thermal and oxidative resistance because the organic binder degrades at high temperatures, the Curie temperature is exceeded, and/or the magnetic material oxidizes, resulting in the loss of magnetic properties. In this regard, the magnetic material 22 has good temperature and oxidation resistance and may be used in applications where other magnetic materials could not survive.

In the illustrated example, the magnetic interface layer 24 has a ceramic matrix 28 (white region) and ferromagnetic regions 30 (black regions) that are dispersed through the ceramic matrix 28. A “layer” is a uniform thickness of material supported on or by another structure. The thickness may be thin relative to the size of the structure.

The ceramic matrix 28 is non-(ferro) magnetic. In one example, the ceramic matrix 28 is an oxide or mixed oxide. The oxide or mixed oxide can include at least one of silicon, aluminum, chromium, yttrium, zirconium, hafnium, and titanium. For instance, the oxide or mixed oxide can include, but is not limited to, silicon dioxide (SiO₂), aluminum oxide (Al₂O₃), mullite, mixed aluminum/silicon oxides or silicates, yttria (Y₂O₃), zirconia (ZrO₂), hafnia (HfO₂), titania (TiO₂), and combinations thereof. In further examples, the ceramic matrix 28 is formed of only one or more of silicon dioxide (SiO₂), aluminum oxide (Al₂O₃), mullite, mixed aluminum/silicon oxides and silicates, yttria (Y₂O₃), zirconia (ZrO₂), hafnia (HfO₂), and titania (TiO₂). The oxide or mixed oxide provides a barrier to oxygen and moisture infiltration and thus protects the ferromagnetic regions 30 from oxidation in high temperature environments.

The ferromagnetic regions 30 are discreet regions, relative to the ceramic matrix 28, of a ferromagnetic metal, intermetallic, oxide. The ferromagnetic metal of the ferromagnetic regions 30 can include at least one of cobalt, iron, nickel, and combinations thereof. Intermetallics can include, but are not limited to, ferromagnetic samarium-containing intermetallics. Example samarium-containing intermetallics can include SmCo₅, Sm₂Co₁₇, or combinations thereof. Ferromagnetic oxides can include Fe₃O₄. In a further example, the ferromagnetic regions 30 are nanosized. The term “nanosized” refers to the maximum dimension of the ferromagnetic regions 30 being 500 nanometers or less.

The fiber core 26 is a solid, elongated body. The length and size of the fibers, F, and thus the fiber cores 26, can be varied depending on the end use. For example, the fibers can be short (chopped) fibers or continuous fibers that are arranged in a desired fiber structure, such as but not limited to woven, non-woven, or three-dimensional fiber structures. As can be appreciated, a fiber structure is one example of a porous structure, and this disclosure also extends to other types of porous structures that are fibrous and non-fibrous.

In the illustrated example, the fiber core 26 has a circular cross-section, but can alternatively have a different cross-sectional geometry. Although not limited, for high performance uses such as aeronautics, aerospace, and the like, the fiber core 26 can be formed of an oxide, carbide, or silicon-based material. One example carbide-based material is silicon carbide, although other carbide-based materials could also be used.

In the magnetic interface layer 24, the ferromagnetic regions 30 provide magnetic properties while the ceramic matrix 28 serves to protect the ferromagnetic regions 30 from thermal degradation and oxidation and, in turn, from loss of the magnetic properties. Thus, the fiber/fiber core 26 and ceramic matrix 28 are non-magnetic and the ferromagnetic regions 30 are magnetic such that the article 20 as a whole is magnetic. For example, the article 20, and more specifically the magnetic material 22, is environmentally and thermally durable and remains magnetic after conditioning in air at a temperature of 800° C. for 100 hours.

FIG. 2 illustrates another example article 120. In this disclosure, like reference numerals designate like elements where appropriate and reference numerals with the addition of one-hundred or multiples thereof designate modified elements that are understood to incorporate the same features and benefits of the corresponding elements. In this example, the article 120 includes a non-magnetic interface layer 132 that is located radially between the magnetic interface layer 24 and the fiber core 26, relative to the central axis of the fiber core 26. For example, the non-magnetic interface layer 132 is non-ferromagnetic and is interfaced at its inside surface with the outer surface of the fiber core 26 and at its outside surface with the inner surface of the magnetic interface layer 24.

The non-magnetic interface layer 132 serves as a mechanical de-bonding layer to control mechanical properties. Additionally, the non-magnetic interface layer 132 can be selected to mechanically and/or environmentally protect the fiber core 26 during fabrication. For example, the non-magnetic interface layer 132 includes at least one of carbon, boron nitride (BN), silicon carbide (SiC), silicon nitride (Si₃N₄), and combinations thereof. In further examples, multiple non-magnetic interface layers 132 of the same or different material composition can be used to provide desired mechanical properties and a desired degree of mechanical, environmental, and thermal protection of the fiber core 26. Additionally or alternatively, one or more non-magnetic interface layers 132 can be arranged radially outboard of the magnetic interface layer 24.

FIG. 3 illustrates another example article 220 that is similar to the article 120 but additionally includes a protective layer 234 located on the magnetic interface layer 24. The magnetic interface layer 24 is radially between the protective layer 234 and the fiber core 26.

As an example, the protective layer 234 serves to protect the magnetic interface layer 24, non-magnetic interface layer 132, and the fiber core 26 from oxidation, heat, or both, but can additionally or alternatively be selected for other purposes. For example, the protective layer 234 serves as an environmental barrier that limits exposure to oxygen and moisture. In further examples, the protective layer 234 includes silicon carbide (SiC), silicon nitride (Si₃N₄), silicon dioxide (SiO₂), alumina (Al₂O₃), chromia (Cr₂O₃), or combinations thereof.

FIG. 4 illustrates another example article 320. In this example, the article 320 includes a plurality of the fibers, F, embedded in a ceramic matrix 336 (white region). The fibers can be any of the fibers described above and can be provided in a desired fiber structure, such as but not limited to a woven fabric. The fibers form a porous structure with interconnected internal pores 338 between the fibers. In this regard, the magnetic interface layer 24 (shown schematically) lines the internal pores 338, and the ceramic matrix 336 lines the magnetic interface layer 24.

In this example, the ceramic matrix 28 of the magnetic interface layer 24 on the fibers is a first ceramic matrix and the ceramic matrix 336 that embeds the fibers is a second ceramic matrix that differs in composition from the first ceramic matrix. The ceramic matrix 336 can be an oxide or a non-oxide. Example non-oxide materials can include, but are not limited to, silicon carbide and silicon nitride. Example oxide materials can include, but are not limited to, silicon oxides, aluminum oxides, mixed oxides or aluminum, mixed oxides of silicon, and combinations thereof.

The fibers can be provided in a desired fiber structure or arrangement, and the ceramic matrix 336 can be deposited around the fibers to embed the fibers. Although the illustrated example discloses a fiber structure, an alternate type of porous structure could be used, such as but not limited to, open-cell foam structures. As will be appreciated, the article 320 can be fabricated in a desired geometry according to the end-use. Such articles can be engine components or sub-components, such as propulsion or land-based gas turbine engine components that require good high temperature and oxidation resistance and that may also benefit from magnetic properties.

A method of fabricating the magnetic material 22 includes forming the ceramic matrix 28 with the ferromagnetic regions 30 dispersed there through. One example process for fabrication of the magnetic material 22 such that it retains magnetic properties after high temperature, oxidative conditioning is sol-gel processing. As a comparison, simply adding a ferromagnetic metal to a ceramic precursor in attempt to form a magnetic ceramic material will not provide the high temperature and oxidation resistance of the magnetic material 22 because the ferromagnetic metal reacts with the precursor during processing to form an oxide of the metal, which is not ferromagnetic. In this regard, the magnetic material 22 can be formed using sol-gel processing to retain magnetism and good high temperature and oxidation resistance in the final material.

In one example, a sol that has the ferromagnetic metal, provided as a salt, and at least one of aluminum and silicon can be applied to a substrate, such as the fiber core 26. The solvent of the sol is then removed to form a gel. The gel is then thermally treated in a chemically reducing environment to form the ceramic matrix 28 and the ferromagnetic regions 30 dispersed through the ceramic matrix 28. As a further example, a fiber structure, such as a fabric, can be dipped into the sol and then allowed to dry. The dipping and drying can be reiterated to obtain a desired thickness.

The ferromagnetic metal can be incorporated into the sol in the form of a hydroxide, followed by conversion of the hydroxide to an oxide by heating in air and then followed by reduction of the oxide in a hydrogen or other reducing environment to the ferromagnetic metal. Alternatively, the hydroxide can be heated directly in hydrogen or reducing atmosphere to reduce to the ferromagnetic metal.

An example of the reaction process, based on cobalt as the ferromagnetic metal, is shown below in EQUATION I and EQUATION II.

Co(C₂H₃O₂)_{2(S)}+2H₂O₍₁₎+Δ(heat)→Co(OH)ₛ₍ₛ₎+2(C₂H₄O₂)_{(aq)} EQUATION I:

Co(OH)₂₍ₛ₎+H_{2(g)}→Co₍ₛ₎+2H₂O_{(g)} EQUATION II:

Further non-limiting examples of sol-gel processing based on cobalt are discussed below. Although cobalt is used in these examples, given this disclosure, one of ordinary skill in the art will be able to select other ferromagnetic metals and salts thereof for sol-gel processing.

Magnetic ceramic matrix composites were fabricated by first dip-coating a magnetic sol around a coated piece of ceramic fabric (previously coated with an interface layer), then infiltrating the fabric with a matrix. Optionally, an oxidation resistant coating was applied over the magnetic sol-gel coating to enhance the oxidation resistance.

Cobalt-doped silica sols were prepared by dissolving cobalt (II) acetate dihydrate into a silica sol-gel solution. Solutions of varying molarities were prepared by dissolving the cobalt (II) acetate dihydrate and the silica sol. Ceramic oxide-based fabric was dipped into the solutions, removed, and allowed to dry. This dipping process can be repeated to increase coating thickness. The coated material was then heated to about 800° C. in an H₂ atmosphere and held for a predetermined amount of time. The final products exhibited magnetic properties, indicating that the cobalt had been reduced to cobalt metal. A solution was also prepared using a smaller amount of cobalt (II) acetate. Once heat treated, it showed a lesser degree of magnetism, indicating that the final magnetism is directly related to the amount of cobalt in the sample.

Cobalt-doped mullite sols were chosen to be the desired interfacial layer for high temperature composites and can provide a higher Curie temperature and a good match in the coefficient of thermal expansion between the magnetic interface layer and a SiNC matrix material. A magnetic mullite precursor sol was also prepared using the alumina and silica sols. This sol was doped with Co using a similar method in which the silica and alumina sols were prepared. Cobalt (II) acetate mullite sols were used in the majority of the ceramic matrix composite fabrication.

A mullite sol was prepared using alumina and silica sols. A cobalt acetate solution was prepared using this sol. Plies of BN/Si₃N₄ coated ceramic oxide-based fabrics were used as substrates for the dip-coating. Plies were dip-coated and then allowed to dry for a predetermined amount of time between dips. The coated plies were heated in a H₂ atmosphere at about 800° C., and then allowed to cool. A ceramic matrix composite was then fabricated using 25 wt % Si₃N₄ mixed with polysilazane as a matrix precursor. The plies were impregnated with the resin, compressed in tooling, and placed in a vacuum. The green body was then pyrolyzed to about 800° C. in N₂. The CMC was still magnetic after the PIP processing.

Ceramic oxide-based fabric was dip-coated in the silica and alumina solutions. The sizing was first removed before the cloth was coated. After drying, the cloth was heated to about 800° C. in an H₂ atmosphere, and held for a predetermined amount of time. The coated fiber showed magnetic properties.

Ceramic matrix composites were fabricated from both oxide and non-oxide fibers. BN/SiC coated and BN/Si₃N₄ coated ceramic fabrics were each used to fabricate samples. The fabric was dip-coated three times in the Co/mullite sol, and allowed to dry between dips. The panels were then heated to about 800° C. in a flowing H₂ atmosphere, and held at that temperature for a predetermined amount of time. The now magnetic plies were laid-up and impregnated with polysilazane mixed with 25 wt % Si₃N₄ filler. The coated fabric was compressed, and placed under vacuum and low heat (150° C.). The panel was subjected to re-impregnations with the polymer and pyrolyzed to about 800° C. in N₂. This repetitive process continued until the panel density reached a density of around 2.2 g/cm³ with a fiber volume of around 40%.

A composite was also fabricated using the Co-doped mullite material. BN/SiC coated ceramic fabric was dip coated in the sol three times, and allowed to dry between each dip. The sample was heated in hydrogen to about 800° C. and held for a predetermined amount of time. The coated cloth was then infiltrated with silicon carbide using chemical vapor deposition.

X-ray diffraction analysis of the Co-doped silica sol heat treated at about 1100° C. showed a small cobalt reflection. The Co-doped alumina sol was heat treated at about 1100° C. was nanocrystalline. SEM analysis showed grain size ranging from 10-50 nm, but are otherwise largely amorphous.

The BN/SiC/Co-doped mullite)/SiC composite was heated to about 800° C. in air. This cycle was repeated a few times. This SiC composite was still very magnetic, capable of adhering to the test magnet. One of the CMC panels was also subjected to the oxidation testing as above. It also retained magnetic properties after the test.

Cobalt metal was added to the mullite sol, and then allowed to gel. The metal reacted with the sol, forming a purple solution similar to the addition of cobalt (II) acetate. The cobalt was presumably oxidized to Co²⁺. Once dried, a purple/grey powder was obtained, but it did not show any magnetic character. A sample of this powder was reduced in hydrogen at about 800° C., and then allowed to cool. The reduced Cobalt/mullite sample was found to be magnetic. This sample was then subjected to an oxidation test at about 800° C. in air.

Plain metallic cobalt has relatively poor oxidation resistance. Conditioning at about 800° C. in air removed all magnetism from the sample. Cobalt metal can be added to the mullite sol, and dissolves readily within. However, the mullite offered no protection to the cobalt metal and the sample had no magnetic character after one day in air at about 800° C.

The articles and magnetic materials disclosed herein can be used in relatively severe operating environments, such as the hot section of a gas turbine engine. Additionally, the magnetic properties can be used to monitor the health state of the material. For continuous fiber-reinforced ceramic matrix composites, a ferromagnetic material could potentially be dispersed through the matrix. However, dispersing the magnetic material in the matrix may interfere with the properties (e.g., oxidation resistance, hardness, thermal expansion, etc.) of the matrix. Further, the method of processing the matrix material may rescind the magnetic properties of the material.

Alternatively, the magnetic material could be incorporated into the fiber-matrix interface. This interface provides a proper balance between bonding/debonding for the mechanical properties of the composite, and also protects the fiber during fabrication. Pyrolytic carbon and boron nitride are used as interfacial materials in high-temperature ceramic matrix composites. Pyrolytic carbon and boron nitride can be deposited by chemical vapor deposition (CVD). Carbon provides good mechanical properties but suffers from poor oxidation resistance. This restricts the use of a carbon interface to applications were the matrix is self-healing (i.e. oxidation inhibited carbon/carbon composites) or in space applications, like rocket nozzles. For more general high-temperature applications, boron nitride or a derivative of boron nitride can be used. Derivatives of boron nitride can include silicon-doped boron nitride or duplex/multi-layer BN/Si₃N₄ combinations. Incorporating a magnetic material into a boron nitride interface would tend to be nitrify or boridize the magnetic material during the CVD process, especially ferromagnetic metals. In this regard, an approach of the present disclosure is to incorporate a magnetic material into a ceramic matrix composite as a separate interface layer. One method to achieve this is sol-gel processing.

Sol-gel chemistry is a versatile medium and allows for synthesis of a diverse array of solid materials, ranging from powders to coatings and monoliths. Sol-gel processing can be low cost and conducted at low temperatures. Sol-gel processing is also a non-line-of-sight coating process that is generally used to deposit oxide coatings. Sol-gel processing involves the reaction of metal alkoxides with either an acid or base and water to form their respective hydroxides. These hydroxides then proceed through a condensation phase to form a gel. The gels are then dried and pyrolyzed to form the metal oxides. The rate of liquid removal plays a role in the microstructure of the final solid. An example of using the sol-gel process to coat a material is dip coating. The thickness of the coating is a function of the viscosity of the solution, speed of withdrawal, and the angle of withdrawal. Thicker coatings can be made by multiple dip coats. Magnetic materials can be made by incorporating a ferromagnetic material into the sol in the form of a hydroxide. The material is then converted from the hydroxide to an oxide by heating in air followed by hydrogen reduction to the metal, or heating the metal hydroxide directly in hydrogen to reduce it to the metal.

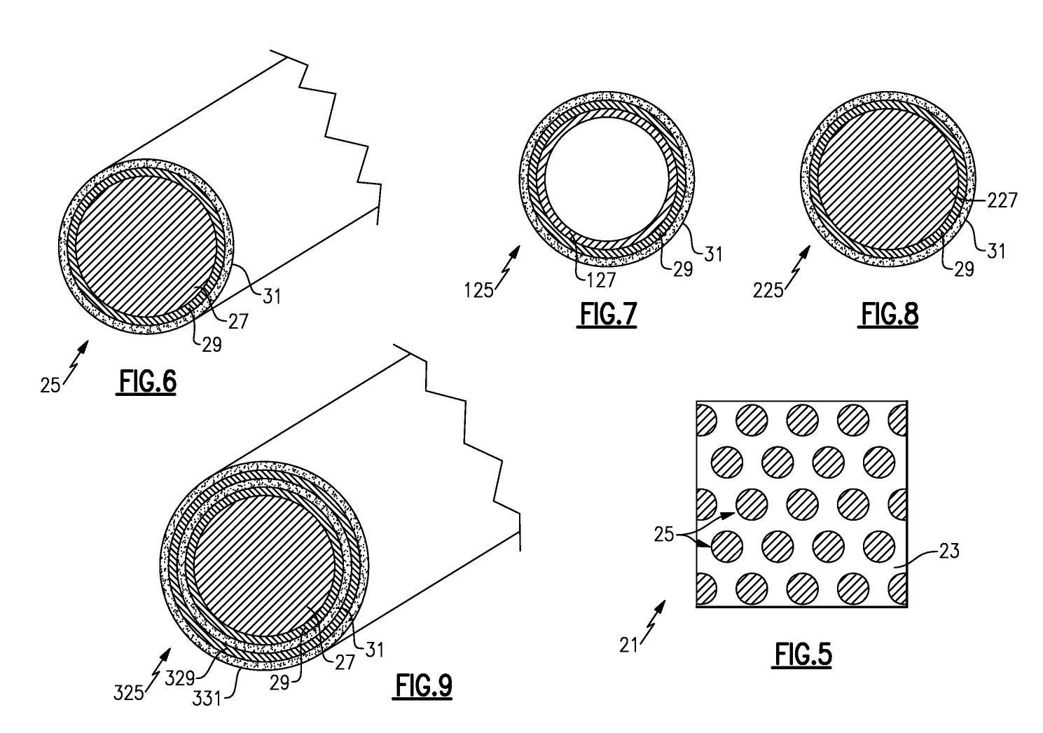

FIG. 5 illustrates an example magnetic article 21 that may be used independently of any of the aforementioned articles. Magnetic materials that have a monolithic structure or that are mixed with organic binders have limited thermal and oxidative resistance because the organic binder degrades at high temperatures and/or the magnetic material oxidizes, resulting in the loss of magnetic properties. In this regard, the magnetic article 21 has good temperature and oxidation resistance and may be used in applications where other magnetic materials could not survive.

The magnetic article 21 includes a ceramic matrix 23 (white region) and a plurality of filler structures 25 dispersed through the ceramic matrix 23. A “filler, “filler structure,” or variation thereof can serve as reinforcement in the magnetic article 21 but is not limited to such a purpose. FIG. 6 illustrates a selected portion of a representative one of the filler structures 25. In this example, the filler structure includes a substrate 27, a ferromagnetic layer 29 around the substrate 27, and a ceramic barrier layer 31 that encloses the ferromagnetic layer 29.

The ferromagnetic layer 29 is formed of a ferromagnetic material that includes a ferromagnetic metal, intermetallic, oxide, or combination thereof. The ferromagnetic metal can include at least one of cobalt, iron, nickel, gadolinium, and combinations thereof. Intermetallics can include, but are not limited to, ferromagnetic samarium-containing intermetallics. Example samarium-containing intermetallics can include SmCo₅, Sm₂Co₁₇, or combinations thereof. Ferromagnetic oxides can include Sr2FeMoO6, CrO2, La0.7Sro.3MnO3, Fe2O3, Fe₃O₄, EuO, or combinations thereof or materials doped with these oxides. The ferromagnetic layer 29 can be formed substantially of, or only of, the ferromagnetic material or materials. In other examples, the ferromagnetic layer 29 can include the ferromagnetic material or materials interdispersed with non-magnetic materials.

The ceramic barrier layer 31 protects the ferromagnetic layer 29 during further fabrication and from thermal degradation, oxidation, or the like. In one example, the ceramic barrier layer 31 includes an oxide material, a nitride material, or combinations thereof. In further examples, the oxide includes silicon oxide, aluminum oxide, chromium oxide, or mixed oxide combinations thereof. The ceramic barrier layer 31 can be formed substantially of, or only of, the oxide material or materials. In other examples, the ceramic barrier layer 31 can include the oxide material or materials interdispersed with non-oxide ceramic materials. Additionally or alternatively, the ceramic barrier layer 31 can be formed of, or include, silicon nitride.

In fabrication processes such as chemical vapor deposition, a vapor is thermally decomposed or reacted with a material to form a matrix. An example process for forming silicon carbide reacts trichloromethylsilane with hydrogen (at temperatures greater than 1000° C.) to form the silicon carbide and HCl. If a metal is used as the ferromagnetic layer 29, and the ferromagnetic layer 29 were not protected by the ceramic barrier layer 31, the HCl would react with the metal to form a gaseous chloride. Similarly, many ceramic processing techniques would expose the metal to high temperatures, reactions products, and/or environment gases that would react with the metal and rescind the magnetic properties.

The ferromagnetic layer 29 and ceramic barrier layer 31 can also be tailored in composition and thickness/size according to a desired use environment and to provide desired magnetic properties.

The ceramic matrix 23 of the magnetic article 21 is selected from carbides, nitrides, oxides, silicides, aluminides, and combinations thereof. In further examples, the ceramic matrix 23 includes as a primary phase, by weight percent, a carbide, nitride, oxide, or combination thereof, and optionally includes one or more additional secondary phases.

The substrate 27 in the example of FIG. 6 is a solid fiber or whisker structure that is elongated and circular in cross-section. Alternatively, the fiber or whisker can be hollow to reduce density of the magnetic article 21.

FIG. 7 illustrates another representative example of a filler structure 125 that can additionally or alternatively be used in the magnetic article 21. In this example, the filler structure 125 includes a hollow substrate 127 instead of the fiber or whisker 27 of the filler structure 25. In one example, the hollow substrate 127 is a hollow microsphere. For example, the microsphere can be formed of silicon dioxide. The hollow substrate 127 facilitates the reduction in density of the magnetic article 21.

FIG. 8 illustrates another representative example of a filler structure 225. In this example, the substrate 227 is a solid particle. For example, the solid particle can be spherical, but is not limited to a spherical geometry.

FIG. 9 illustrates another representative example of a filler structure 325. The filler structure 325 is similar to the filler structure 25 but includes an additional ferromagnetic layer 329 and an additional ceramic barrier layer 331. The ferromagnetic layers 29/329 and the ceramic barrier layers 31/331 are alternately arranged. As can be appreciated, additional ferromagnetic layers and ceramic barrier layers can also be used. Moreover, the filler structure 325 could also include interface layers in between any of the ferromagnetic layers and the ceramic layers and/or between the substrate 27 and any of the layers. Example interface layers can include carbon, boron nitride, silicon nitride, silicon carbide, and combinations thereof, to control mechanical properties of the magnetic article 21. Additionally, the filler structures 25/125/225/325 can be used in any combination with each other, or in combination with non-magnetic filler of fillers.

A method of fabricating the magnetic article 21 can include depositing the ferromagnetic layer 29 around the substrate 27/127/227 and then depositing the ceramic barrier layer 31 to enclose the ferromagnetic layer 29. In this regard, the ceramic barrier layer 31 is continuous and surrounds the ferromagnetic layer 29 such that the ceramic barrier layer 31 limits oxygen and moisture infiltration to the ferromagnetic layer 29 and thermally shields the ferromagnetic layer 29. Further non-limiting examples are described below.

A. Fabrication of Magnetic Filler

1. Hydroxyl Reduction

A solution of cobalt nitrate was made by dissolving Co(NO₃)₂.6H₂O in de-ionized water. Hollow mullite spheres and the Co(NO₃)₂ solution were mixed together. The mixture was dried in a drying oven at 100° C. The resulting mixture was then reduced under hydrogen to form the metallic coating. These coatings were found to be highly magnetic. Similar procedures were carried out on hollow spheres, continuous fibers, whiskers, and woven fabric. The fibers used were non-oxide based ceramic cloth or oxide based cloth. Iron and nickel coatings were also deposited on the same material. For these materials, similar procedures were followed using Fe(SO₄) dissolved in de-ionized water for iron and Ni(OH)₂ in DI water for nickel as the precursors. It is to be understood that other solvents could alternatively be used.

2. Chemical Vapor Deposition

Another example method for synthesizing a magnetic article is by chemical vapor deposition of iron from iron pentacarbonyl. Hollow spheres formed of silica and alumina and filled with gas were loaded into a tube packed with glass wool on either end to form a deposition zone holding the spheres in place. A reactor was heated to 300° C. under argon purge. Then iron pentacarbonyl was introduced. The tube can be agitated continuously or at time intervals to prevent the spheres from sticking together. The reactor was cooled under argon purge.

3. Electroless Deposition

Another example method to coat microspheres with magnetic material is by electroless plating. As an example, nickel was deposited on hollow spheres formed largely of silica and alumina and filled with gas. The spheres were first degreased A plating bath was mixed containing a 45 wt % nickel sulfate solution, a solution of 25 wt % sodium hypophosphite and 1 wt % ammonium hydroxide, and de-ionized water. The solution was then brought to 90-100° C. on a stirring hotplate, the degreased spheres were added, and the bath was covered. The coating process was expedited by placing aluminum foil in the bath. The spheres were allowed to coat for 1-4 hours, while the volume of the bath was maintained with the addition of de-ionized water. The spheres were then collected using filtration, rinsed with de-ionized water and air dried. A permanent magnet was used to verify magnetism of the particles.

4. CVD of Protective Coating

Silicon dioxide coatings were deposited using chemical vapor deposition. These coatings were all deposited by the thermal decomposition of tetraethylorthosilicate (TEOS) in the presence of either nitrogen, argon, or hydrogen. The deposition temperature was varied from 500° C. to 700° C. To deposit the SiO₂ coatings, either nitrogen, argon, or hydrogen was bubbled through TEOS. The bubbling time controls the desired thickness of the coating. This process was performed at either reduced or atmospheric pressure. Once the temperature had stabilized, flow was redirected through a bubbler filled with TEOS.

For silicon carbide protective coatings, a flash coating of silicon dioxide was first deposited (under the conditions listed above). The silicon carbide was then deposited using chemical vapor deposition of methyltrichlorosilane. The reactor was heated to over 1000° C. under argon, and silicon carbide was deposited by bubbling hydrogen through MTS. The reactor was cooled under flowing argon.

The same procedures were applied to continuous fiber and fiber whiskers for use in a polymer-infiltration-pyrolysis composite. Iterations of each coating were produced if a multi-layered system was desired.

B. Fabrication of Magnetic Article

A coated substrate (fiber whiskers, created as described above) were combined with Starfire SMP-10 and mixed until combined. The material was heated under nitrogen to about 300° C. and held for a predetermined time. The solid was removed and transferred to a furnace, then heated to over 1000° C. and held for a predetermined time.

A typical Chemical Vapor Infiltration (CVI)-SiC matrix composite was fabricated as follows. Single strand unidirectional composites were fabricated by first coating oxide or non-oxide fibers with an interfacial material. The interfacial material is used to provide the correct bonding/debonding properties in a ceramic matrix composite. The multi-layered magnetic material was then applied over the interfacial coated tows. Silicon carbide was infiltrated into the tow by reacting hydrogen with trichloromethylsilane at over 1000° C. These unidirectional single strand composites were tested for magnetic properties using a permanent magnet. Magnetic materials containing the SiO₂ protective coating survived the silicon carbide infiltration.

All materials were tested for oxidation resistance by heating to about 800° C. in air for 36 hours and magnetic properties were retained.

The magnetic articles disclosed herein can be used in aerospace and other applications subject to high temperature exposure and oxidizing environments, but are not limited to such uses. The magnetic articles can be fabricated using inexpensive components and processing, while reducing density of the final material.

Although a combination of features is shown in the illustrated examples, not all of them need to be combined to realize the benefits of various embodiments of this disclosure. In other words, a system designed according to an embodiment of this disclosure will not necessarily include all of the features shown in any one of the Figures or all of the portions schematically shown in the Figures. Moreover, selected features of one example embodiment may be combined with selected features of other example embodiments.

The preceding description is exemplary rather than limiting in nature. Variations and modifications to the disclosed examples may become apparent to those skilled in the art that do not necessarily depart from the essence of this disclosure. The scope of legal protection given to this disclosure can only be determined by studying the following claims.

What is claimed is:

1. An article comprising:
at least one fiber that includes a fiber core; and
an interface layer that extends around the fiber core, and the interface layer includes a first ceramic matrix and ferromagnetic regions dispersed through the first ceramic matrix.

2. The article as recited in claim 1, wherein the first ceramic matrix is an oxide.

3. The article as recited in claim 1, wherein the first ceramic matrix is an oxide of at least one of silicon, aluminum, chromium, yttrium, zirconium, hafnium, and titanium.

4. The article as recited in claim 3, wherein the ferromagnetic regions include cobalt metal.

5. The article as recited in claim 1, wherein the ferromagnetic regions include at least one of cobalt metal, iron metal, nickel metal, samarium metal, oxide, and ferromagnetic intermetallic.

6. The article as recited in claim 1, wherein the ferromagnetic regions are nanosized.

7. The article as recited in claim 1, wherein the fiber core is formed of at least one of an oxide, carbide, and silicon-based material.

8. The article as recited in claim 1, further comprising a non-magnetic interface layer that is located radially between the fiber core and the interface layer.

9. The article as recited in claim 8, wherein the non-magnetic interface layer includes at least one of carbon, boron nitride, silicon nitride, and silicon carbide.

10. The article as recited in claim 1, further comprising a second ceramic matrix differing in composition from the first ceramic matrix, the second ceramic matrix embedding the at least one fiber and the interface layer.

11. The article as recited in claim 1, further comprising a protective layer that is located on the interface layer such that the interface layer is located radially between the protective layer and the fiber core.

12. The article as recited in claim 11, wherein the protective layer includes at least one of silicon carbide, silicon nitride, silicon dioxide, alumina, and chromia.

13. A method of fabricating an article, the method comprising:
forming an interface layer around a fiber core of at least one fiber, the interface layer includes a first ceramic matrix and ferromagnetic regions dispersed through the ceramic matrix.

14. The method as recited in claim 13, wherein the forming includes forming the first ceramic matrix and the ferromagnetic regions using a sol-gel process.

15. The method as recited in claim 14, including applying to the fiber core a sol that has a ferromagnetic metal and at least one of aluminum, silicon, chromium, yttrium, zirconium, hafnium, and titanium.

16. The method as recited in claim 15, including removing solvent from the sol to form a gel, and thermally treating the gel to form the first ceramic matrix and the ferromagnetic regions.

17. A magnetic article comprising:
a ceramic matrix; and
a plurality of filler structures dispersed through the ceramic matrix, at least one of the filler structures includes a substrate, a ferromagnetic layer around the substrate, and a ceramic barrier layer that encloses the ferromagnetic layer.

18. The magnetic article as recited in claim 17, wherein the ferromagnetic layer is selected from the group consisting of cobalt metal, iron metal, nickel metal, gadolinium metal, oxide, and combinations thereof.

19. The magnetic article as recited in claim 17, wherein the substrate is selected from the group consisting of a fiber, a hollow particle, and a solid particle.

20. The magnetic article as recited in claim 1, wherein the ceramic barrier layer includes an oxide.
